(19) United States
(12) Patent Application Publication
(10) Pub. No.: US 2025/0309030 A1
(43) Pub. Date: Oct. 2, 2025

(54) MICROELECTRONIC STRUCTURES INCLUDING IHS COUPLING ENHANCEMENT STRUCTURES FOR THERMAL DEGRADATION MITIGATION

(71) Applicant: Intel Corporation, Santa Clara, CA (US)

(72) Inventors: Wei Gong, Mesa, AZ (US); Sergio Antonio Chan Arguedas, Chandler, AZ (US); Ziyin Lin, Chandler, AZ (US); Kumar Abhishek Singh, Phoenix, AZ (US)

(73) Assignee: Intel Corporation, Santa Clara, CA (US)

(21) Appl. No.: 18/622,910

(22) Filed: Mar. 30, 2024

(51) Int. Cl. H01L 23/367; H01L 21/50; H01L 23/00; H01L 25/16

(52) U.S. Cl. CPC H01L 23/3675; H01L 21/50; H01L 24/32; H01L 25/167; H01L 24/16; H01L 24/73; H01L 2224/16225; H01L 2224/32225; H01L 2224/32245; H01L 2224/73204; H01L 2224/73253; H01L 2924/1432

(57) ABSTRACT

Microelectronic integrated circuit package structures include a package substrate and an integrated heat solution (IHS) over the package substrate. The IHS comprises a lid and a foot proximal an opening in the HIS. A support structure is spaced apart from the foot and comprises a first interface material in contact with the package substrate. The lid is in contact with the support structure and a second interface material is directly between the foot of the IHS and the package substrate. A die is on the package substrate adjacent to the support structure, the die having an optical interface proximal to the opening.

### GOVERNMENT INTEREST STATEMENT

This Invention was made with Government support under Agreement No. N00164-19-9-0001, awarded by NSWC Crane Division. The Government has certain rights in the Invention.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

In optical packaging structures, optical dies are attached on special substrates which may have a cut-out region under optical dies to facilitate the attachment of fiber array units (FAUs) to the optical die. In conventional IC packaging, a thermal solution such as an integrated Heat Spreader (IHS) with a foot fully attached on the substrate as a closed loop. However, in optical packaging, the IHS has openings at specific locations to accommodate the placement of the FAU. The strength of the coupling between the IHS and the package substrate near the IHS opening may become weak and dynamic warpage during operation of the optical package structure/system may be larger as compared to such coupling farther away from the FAU opening.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a cross-sectional views of IC package structures comprising coupling enhancement structures, in accordance with some embodiments.

FIGS. 1B-1D are top view of IC package structures comprising coupling enhancement structures, in accordance with some embodiments.

FIG. 1E is a cross-sectional views of IC package structures comprising coupling enhancement structures, in accordance with some embodiments.

FIG. 1F is top view of IC package structures comprising coupling enhancement structures, in accordance with some embodiments.

FIG. 2A is a cross-sectional view of an IC package structure comprising coupling enhancement structures, in accordance with some embodiments.

FIG. 2B is a cross-sectional view of an IC package structure comprising an IHS, in accordance with some embodiments.

FIG. 2C is cross-sectional view of an IC package structure comprising an IHS foot delta, in accordance with some embodiments.

FIG. 2D is top view of an IC package structure comprising an IHS, in accordance with some embodiments.

FIGS. 3A-3D are cross-sectional views of IC package structures comprising methods of forming coupling enhancement structures, in accordance with some embodiments.

FIGS. 4A-4D are cross-sectional views of IC package structures comprising forming coupling enhancement structures on an IHS foot, in accordance with some embodiments.

FIG. 5 is a cross-sectional view of an IC package structure comprising IHS coupling enhancement structures, in accordance with some embodiments.

FIG. 6A-6B illustrate flow charts of processes for the fabrication of IC package structures having IHS coupling enhancement structures, in accordance with some embodiments.

FIG. 7 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods of providing structures for the mitigation of thermal degradation of optical packages, such as those coupled to a fiber array unit (FAU). An integrated heat spreader structure (IHS) which may couple to a package substrate may typically have a foot portion which attached to the package substrate. An opening within the IHS is provided for the attachment of an FAU to optical dies which are on the package substrate. At the specific location of the IHS opening, the coupling between IHS and the package substrate may become weak and there may be a difference between dynamic warpage near the FAU opening as compared with IHS coupling with the package substrate at locations farther away from the FAU opening. This difference can lead to greater thermal interface material (TIM) degradation of die attached to the IHS with the TIM material.

The embodiments herein include IHS coupling enhancement structures which mitigate the thermal degradation issues described above. In an embodiment, one or more structural support features, such as metal strips, may be placed on the package substrate near an integrated heat spreader (IHS) opening side. An interface material connects the package substrate and the IHS to the structural support feature. The use of the support features significantly enhances the local coupling between package substrate and the IHS near the FAU opening and suppresses dynamic warpage within the package structure to enable low warpage optical package structures.

In another embodiment, an IHS may comprise a foot extension to enhance the coupling between a package substrate and the IHS near an FAU opening location of the IHS. A high elastic modulus adhesive material is utilized to couple the IHS foot extension with the package substrate. In other locations farther from the IHS openings, the IHS is attached to the package substrate by a low modulus adhesive material.

Embodiments herein describe methods of fabricating package structures, such as optical packaging systems/structures having IHS coupling enhancement structures to mitigate thermal degradation. In an embodiment a package substrate may be coupled with an integrated heat spreader (IHS) that is over the package substrate. The IHS comprises a lid, a first foot portion proximal an opening in the IHS and a second foot portion spaced apart from the opening by the first foot portion. The first foot portion extends a greater length from the lid than the second foot portion. The first foot portion of the IHS may be bonded with a first interface material to the package substrate, and the second foot portion may be bonded to the package structure with a second interface material, wherein the first interface material comprises a higher elastic modulus than the second interface material.

In another embodiment, a package substrate may be coupled with an IHS that is over the package substrate. The IHS comprises a lid and a foot proximal an opening in the IHS. A structural support feature is spaced apart from the foot where a first interface material is in contact with the package substrate, and the lid is in contact with the structural support. A second interface material is directly between the foot of the IHS and the package substrate. Optical dies are on the package substrate adjacent to the structural support feature.

The architecture described herein may be assembled and/or fabricated with one or more of the features or attributes provided in accordance with various embodiments. A number of different assembly and/or fabrication methods may be practiced to enable the formation of coupling enhancement structures for optical package systems which mitigate thermal degradation of such package systems, according to one or more of the features or attributes described herein.

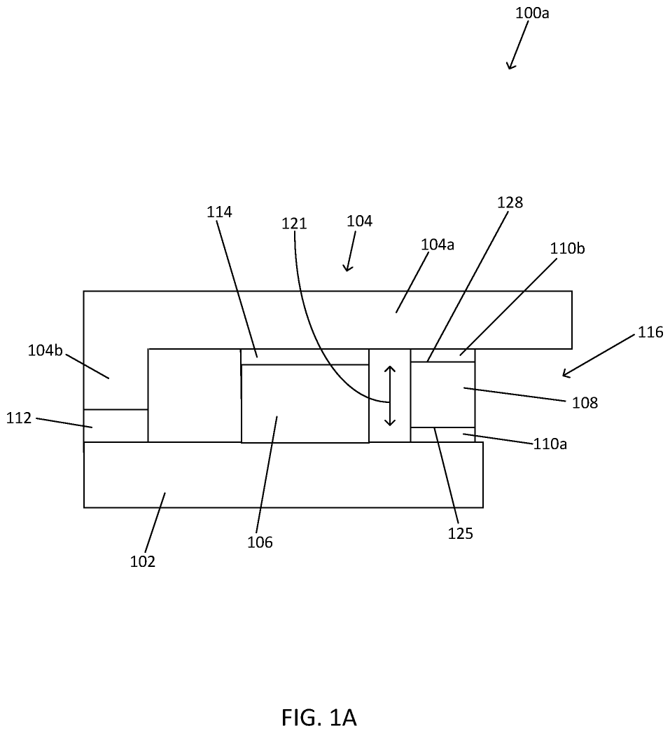

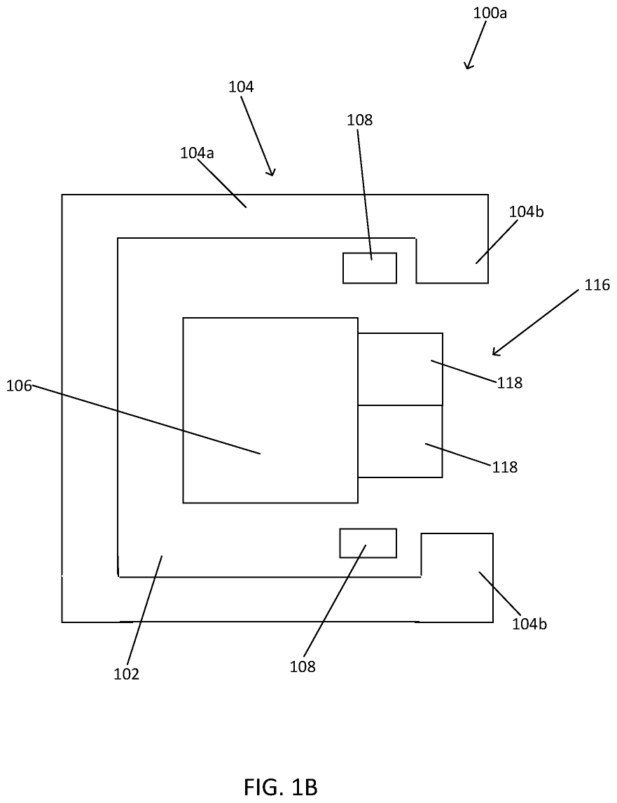

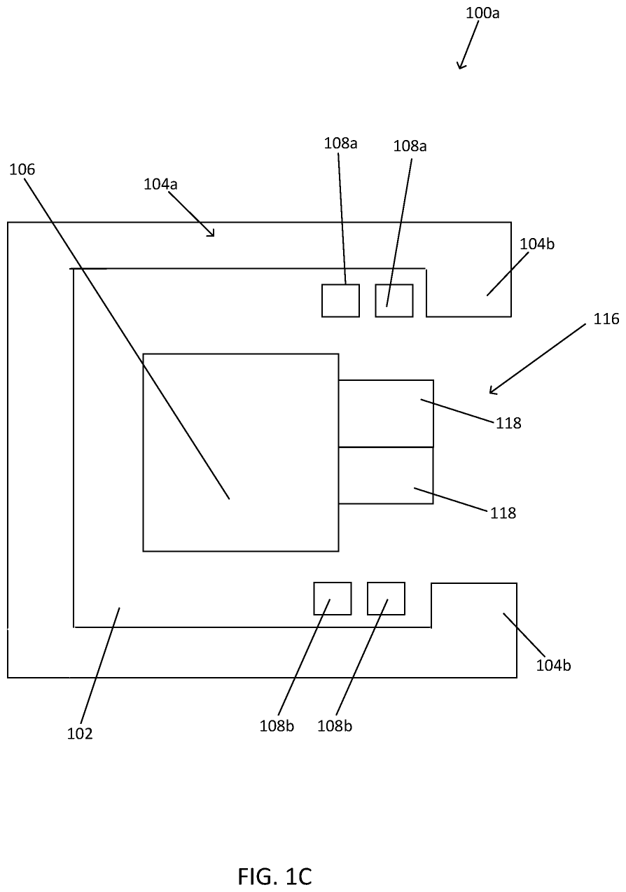

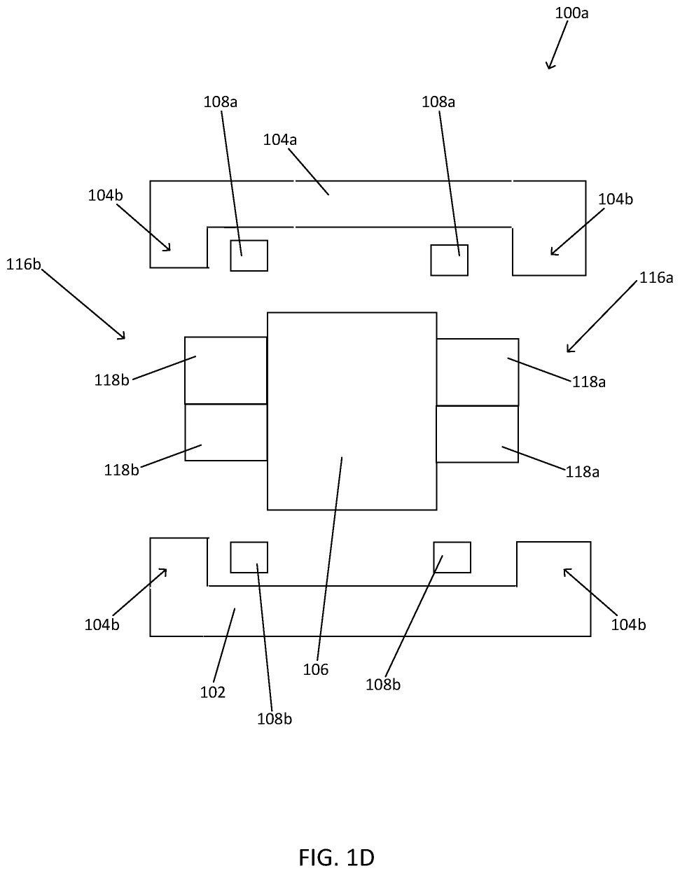

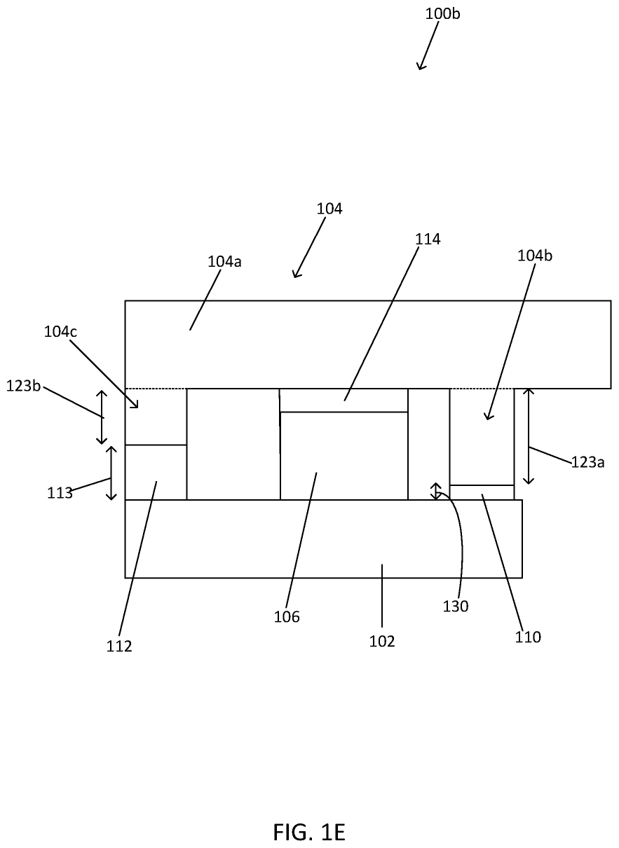

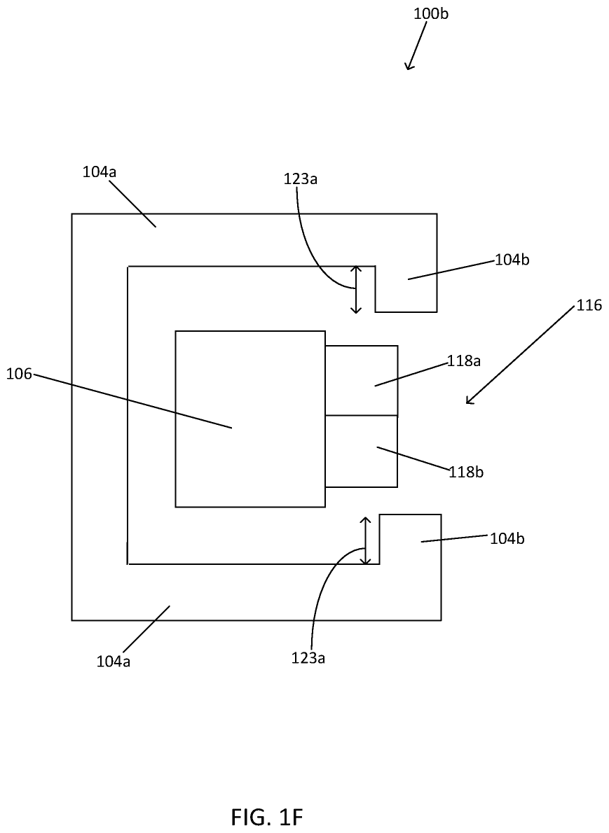

FIGS. 1A-1F illustrate embodiments of optical package structures including optical die. The package structures are formed utilizing standard IC processing techniques. The methods of fabrication described herein create improved device performance in advanced 2.5D and 3D packaging.

FIG. 1A is a cross-sectional view of a portion of integrated circuit (IC) photoelectronic package structure 100a, in accordance with some embodiments. As shown, package substrate 102 may comprise mechanical support and electrical connectivity for die, such as logic die and/or optical die that may be attached to the package substrate 102. The package substrate 102 may comprise an interposer or a board in an embodiment. A die 106 may be on the package substrate 102, wherein the die 106 may comprise a central processing unit (CPU) or a field programmable gate array (FPGA) die, for example or may comprise any suitable logic die for the particular application.

An interface material 112 may be on the substrate 102 adjacent to the die 106. The interface material 112 may comprise a silicone material in an embodiment. The interface material 112 may comprise a thickness of between about 100 to about 200 microns in an embodiment and may comprise an elastic modulus of about 20 MPa or less. An integrated heat spreader (IHS) 104 may comprise a thermal solution and may be thermally and mechanically coupled to the package substrate 102 and to the die 106, wherein a thermal interface material (TIM) 114, may couple the die 106 to the IHS 104. The IHS 104 may comprise a conductive material, such as a metal material, and may comprise a lid portion 104a and a foot portion 104b. The foot portion 104b is perpendicular to the lid portion 104a and is coupled with the package substrate 102. The lid portion 104a is proximate to an opening 116 in the IHS 104 which provides for the coupling of a fiber array unit (FAU), not shown) which may couple optical die (as shown in FIG. 1B) to optical fiber for transmission of electromagnetic signals between the optical fiber and the optical die.

The interface material 112 may comprise any suitable thickness or materials which provide stress absorbance during thermal stress of the package structure 100. A support structure 108 is between the lid portion 104a of the IHS 104 and the package substrate 102, wherein a first portion of an additional interface material 110a couples/bonds a bottom surface 125 of the support structure 108 to the package substrate 102 and a second portion of the additional interface material 110b couples/bonds a top surface 128 of the support structure 108 to the lid portion 104a of the IHS 104. In an embodiment, the additional interface materials 110a, 11b may comprise a first portion of the interface material 110a and a second portion of the interface material 110b. The interface material 112 may comprise a second interface material 112.

The support structure 108 may comprise any suitable material with which to provide mechanical support for the coupling of the IHS to the substrate. In an embodiment, the support structure 108 may comprise a conductive material such as a metal material in an embodiment. The support structure 108 may comprise such materials as copper or copper alloys or may comprise any other suitable conductive materials as may be required by the particular application. The support structure 108 may comprise a thickness 121 that may be optimized for a particular application.

The first and second portions of the first interface materials 110a, 110b may comprise an electrically conductive adhesive (ECA) material in an embodiment or may comprise a non-conductive adhesive material (NCA), in another embodiment. The first portion of the first interface material adhesive material 110a and the second portion of the first interface material 110b may comprise the same adhesive materials as each other or they may comprise different adhesive materials from each other. The first and second portions of the first interface materials 110a, 110b may comprise an elastic modulus that is about 10 MPa to about −10 GPa in an embodiment. The use of the first interface material 110 to enhance the strength of the IHS 104 coupling to the package substrate 102 in local areas such as near the opening 116 in the IHS 104 is advantageous since it minimizes possible damage to the die 106 during thermal cycling.

The use of both the second interface material 112 farther from the IHS opening 116 and the first interface material 110 closer to the IHS opening 116 allows for the softer second interface/sealant material 112 on the IHS foot 104b to absorb stress induced during dynamic warpage. The stronger first interface material 110 mitigates dynamic warpage near the IHS opening 116 region since the first interface material 110 possesses a much higher modulus than the second interface sealant 112 material. Thus, the IHS 104 near the opening 116 region may comprise an enhanced coupling with the package substrate 102. The TIM 114 may be between the lid portion 104a of the IHS and the die 106. In an embodiment the TIM 114 may comprise a PTIM (polymer based thermal interface material) and may comprise such materials as thermal grease material.

FIG. 1B is a top view of a portion of IC package structure 100a, such as an optical IC package structure in accordance with some embodiments. As shown, a package substrate 102 may comprise an interposer or a board in an embodiment. A die 106 may be on the package substrate 102, wherein the die 106 may comprise a central processing unit (CPU) or a field programmable gate array (FPGA) die, for example or may comprise any suitable die, such as a logic die for example, according to the particular application. Optical die 118 may be coupled to the die 106. The optical die 118 are proximate to an opening 116 region of an IHS 104 which allows for the coupling of a FAU (not shown) to the optical die 118.

The optical die 118 may comprise die which integrate photonic functions for information signals imposed on electromagnetic optical wavelengths. The optical die 118 may comprise any suitable optical die/IC 118 such as any optical devices configured to transmit and/or process information imposed on electromagnetic signals to include information to convert electromagnetic signals to electrical signals. In an embodiment, the optical die 118 may be configured to transmit and/or process signals of any suitable wavelength, such as electromagnetic signals in near infrared, infra-red, radio frequency or microwave wavelengths, for example.

Support structures 108, which may comprise metal strips in an embodiment, may be placed near the opening 116 in the IHS 104 to enhance coupling between the IHS 104 and the package substrate 102. Any number of support structures 108 may be placed proximate to the opening 116, and the number and location of the support structures may be optimized for the particular package structure design. FIG. 1C depicts an embodiment wherein two sets of support structures 108a, 108b, are located on either side of the IHS 104 opening 116. FIG. 1D depicts an embodiment wherein the package structure 100a comprises two IHS 104 openings 116a, 116b wherein support structures 108a, 108b may be placed proximate to the openings 116a, 116b.

Optical dies 118a, 118b are coupled to the die 106 and are proximate to the openings 116a, 116b respectively. The support structures 108 may be strategically employed support structures to enhance the local coupling at IHS 104 locations such as the foot locations 104a near the openings 116a, 116b. Strong, high modulus interface materials utilized to couple the support structures 108 with both the package substrate 102 and the IHS 104 significantly increase the coupling strength between IHS 104 and the package substrate on the IHS foot opening 104b sides. The embodiments herein significantly suppress dynamic warpage during thermal cycling and thus mitigate the degradation of thermal interface material 114 between the die 106 and the IHS 104.

FIG. 1E is a cross-sectional view of a portion of integrated circuit (IC) package structure 100b, such as an optical package structure/system in accordance with some embodiments. As shown, package substrate 102 may comprise mechanical support and electrical connectivity for die 106, such as logic die 106 and/or optical die that may be attached to the package substrate 102. The package substrate 102 may comprise an interposer or a board in an embodiment. The die 106 may be on the package substrate 102, wherein the die 106 may comprise a central processing unit (CPU) or a field programmable gate array (FPGA) die, for example or may comprise any suitable logic die for the particular application.

An interface material 112 may be on the substrate 102 adjacent to the die 106. The interface material 112 may comprise an epoxy or silicone based material in an embodiment. The interface material 112 may comprise a thickness 113 of between about 100 to about 200 microns in an embodiment and may comprise an elastic modulus of about 20 MPa or less. A thermal solution such as an integrated heat spreader (IHS) 104 may be thermally and mechanically coupled to the package substrate 102 to the die 106, wherein a thermal interface material (TIM) 114 may couple the die 106 to the IHS 104. The TIM 114 may comprise a polymer-based TIM in an embodiment.

The IHS 104 may comprise a conductive material, such as a metal material, and may comprise a lid portion 104a, a first foot portion 104b and a second foot portion 104c. The first and second foot portions 104b, 104c are perpendicular to the lid portion 104a and are coupled with the package substrate 102. The first foot portion 104b is proximate to an opening 116 in the IHS 104 which provides for the coupling of a fiber array unit (FAU, not shown) which may couple optical die (as shown in FIG. 1F) to optical fiber of an FAU for transmission of electromagnetic signals between the optical fiber and the optical die. The second foot portion 104c is distal to the opening 116 with respect to the first foot portion 104b. The first foot portion 104b comprises a length 123a which is greater than a length 123b of the second foot portion 104c. In an embodiment, the length 123a of the first foot portion 104b may comprise a length that is about 160 microns to about 180 microns greater than the length 123b of the second foot portion 104c, but the difference in the lengths 123a, 123b may be optimized for the particular design requirements.

The interface material 112 may comprise any suitable thickness or materials which provide stress absorbance during thermal stress of the package structure 100. The first foot portion 104b is coupled to the package substrate 102 by an additional interface material 110. In an embodiment, an additional interface material 110 may comprise a first interface material and the interface material 112 may comprise a second interface material 112. The first interface material 110 may comprise an ECA material in an embodiment or may comprise a NCA in another embodiment. The first interface material 110 may comprise an elastic modulus that is about 100 MPa to about 10 GPa in an embodiment and may comprise a thickness 130 of between about 10 microns to about 20 microns in an embodiment. In an embodiment, a thickness 113 of the second interface material 112 is greater than a thickness 130 of the first interface material 110. The first interface material 110 may be employed to enhance the strength of the IHS 104 coupling in local areas such as near the opening 116 in the IHS 104.

Strengthening the coupling in the opening region 116 of the IHS 104 is advantageous since it minimizes possible TIM degradation during thermal cycling. The first foot portion 104b comprises an extension of the IHS 104 foot which is bonded to the package substrate 102 with the stronger first interface 110 material proximate to the opening 116, while the second foot portion 104b of the IHS 104 is bonded with the package substrate 102 by the second 112.

FIG. 1F depicts a top view of a package structure 100b, such as the package structure 100b of FIG. 1E for example. Optical dies 118a, 118b are coupled to the die 106 and are proximate to the opening 116. The first foot portions 104b (which may comprise a foot extension 104b with greater length 123a) proximate to the opening 116 enhance the local coupling at IHS 104 locations (such as at the foot locations 104b) since they are coupled to the package substrate 102 with the first interface material 110. The embodiments herein significantly suppress dynamic warpage during thermal cycling and thus mitigate the degradation of thermal interface material 114 between the die 106 and the IHS 104.

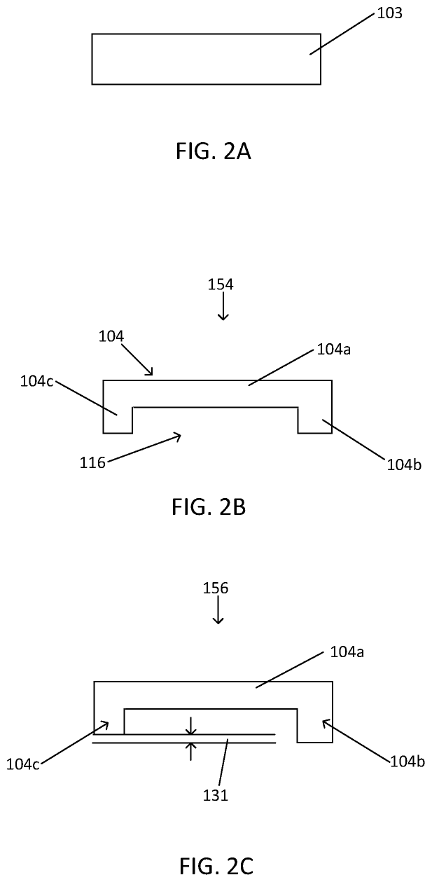

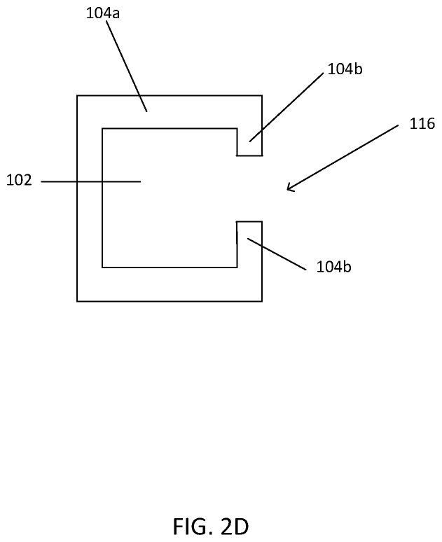

FIGS. 2A-2D illustrate embodiments of forming IC package structures (such as the IC package structures of (FIGS. 1A-1F), for example. FIG. 2A depicts a cross-sectional view of a portion of a metal piece 103 according to some embodiments. As shown the metal piece 103 may comprise any suitable materials or combination of materials with which to form an IHS for an optical device structure. In FIG. 2B, a process 154 may be employed to form the IHS 104. The IHS 104 is formed to comprise a lid portion 104a, and first and second foot portions 104b, 104c respectively. The IHS 104 may be formed utilizing any advantageous processes as are known in the art, such as by using a hybrid method including a stamp and machining method. The machining process for optical package IHS structures enables the formation of an opening 116 in the IHS 104 foot regions 104a, 104b. This opening 116 may be utilized for FAU attachment purposes.

In FIG. 2C a process 156 may be employed, such as a machining process, wherein a portion 131 of the second foot portion 104c of the IHS 104 may be removed. The portion 131 of the second foot portion 104c that may be removed may comprise about 180 microns in some embodiments but may comprise between about 100 to about 300 microns in other embodiments. Thus, the first foot portion 104b, which may comprise a foot extension 104b may comprise a greater length than a length of the second foot portion 104c as depicted in FIG. 1E for example. As depicted, one location is shown for the foot extension 104b creation but any number of extensions may be created in different locations according to the particular design requirements. FIG. 2D depicts a top view of first foot portions 104b near opening 116, wherein the first foot portions 104b are bonded with the first interface material 110 to the package substrate 102 as shown in FIG. 1E for example.

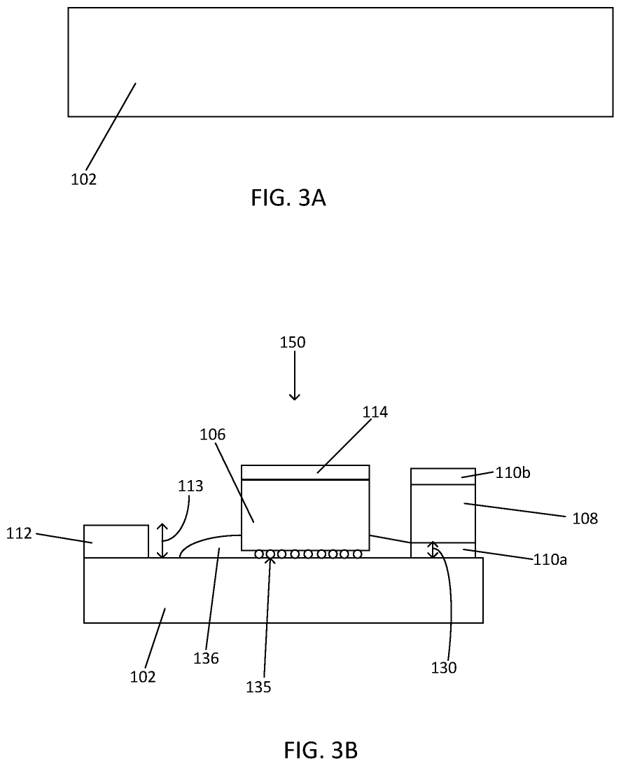

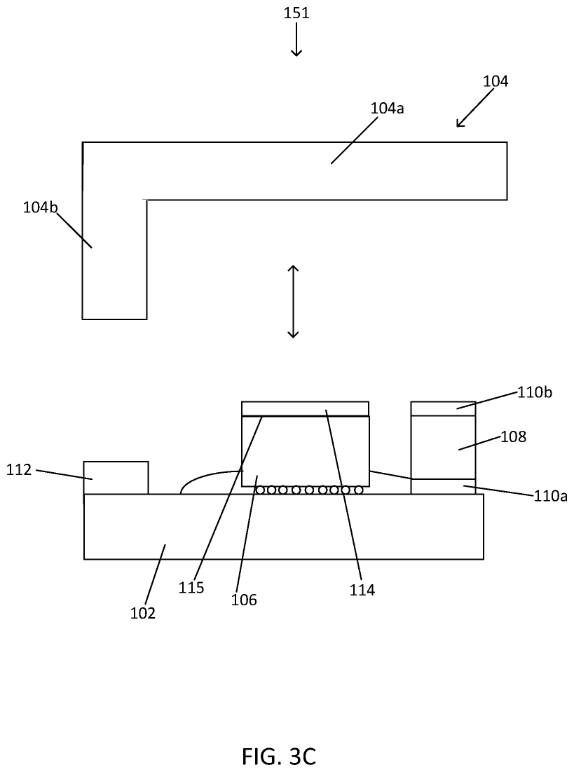

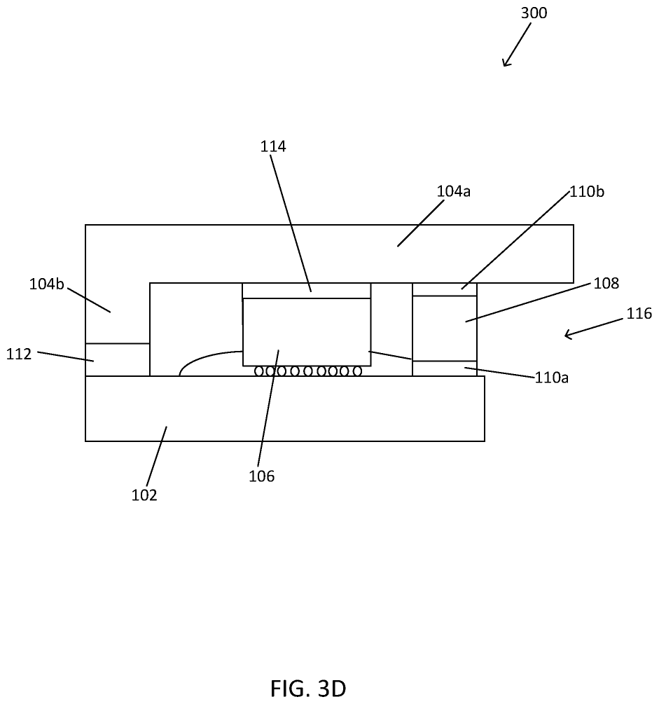

FIGS. 3A-3D depict a method of fabricating a package structure such as the package structure depicted in FIG. 1A for example. FIG. 3A depicts a portion of a package substrate 102. The package substrate 102 may comprise any suitable substrate with which to attach die and build an optical package structure thereupon. In an embodiment the package substrate 102 may provide mechanical support and provide electrical communication within a package structure and between devices coupled with such a package structure. In an embodiment the package substrate 102 may comprise an interposer or a board.

In FIG. 3B a process 150 may include an attachment process, wherein a die 106 may be attached to the substrate 102 by solder balls 135 and an underfill material 136 may be formed around the solder balls 135. Optical die (not shown) may be attached adjacent to the die 106. An interface material 112, which may comprise a silicone-based material in an embodiment, may be formed on the package substrate 102 adjacent to the die 106 utilizing a dispensing or stencil application, for example. The interface material 112 may comprise a thickness 113 of between about 100 microns to about 200 microns in an embodiment. The die 106 may comprise a central processing unit (CPU) or a field programmable gate array (FPGA) die, for example or may comprise any suitable logic die for the particular application.

The die 106 may be attached utilizing any suitable die attach process, as are known in the art. Process 150 may additionally include the formation of an additional interface material 110 that may be formed adjacent to the die 106. In an embodiment, the additional interface material 110 may comprise a first interface material 110 and the interface material 112 may comprise a second interface material 112 and may be cured subsequent to formation.

A first portion of the first interface material 110a may be formed on the package substrate 102 and a second portion of the first interface material 110b may be formed on a top surface of the die 106 utilizing a dispensing process or a screen/stencil or printable process, for example, wherein the first interface material 110 may be cured. In an embodiment, the first interface material 110 may comprise an electrically conductive adhesive material (ECA), for example. The first interface material 110 may comprise a thickness 130 of between about 10 microns to about 20 microns, in an embodiment. Process 150 may further comprise a support structure 108 placement/formation process, wherein a support structure 108 may be formed on a first portion of the adhesion material 110a by utilizing any suitable process as is known in the art. In an embodiment, the support structure 108 may comprise a metal material such as a copper or copper alloy material for example. A thermal interface material (TIM) 114 may be formed on a surface 115 of the die 106 and may be cured.

FIG. 3C depicts an attachment process 151 wherein an IHS 104 is attached to the substrate 102. In an embodiment, the IHS 104 may comprise a lid portion 104a and a foot portion 104b. The lid portion 104a is attached to the TIM 114 and the first interface material 110b, and the foot portion 104b is attached to the second interface material 112. In an embodiment, the TIM 114 may comprise a polymer based TIM material. In an embodiment, a top surface of the TIM 114 may be coplanar with a top surface of the first interface material 110b.

FIG. 3D depicts package structure 300 subsequent to the attachment process 151. By utilizing the support structure 108 attached to the IHS 104a and the package structure 102 with the first interface materials 110b, 110a respectively, coupling between the package substrate 102 and the IHS 104 is enhanced at the IHS opening region and thus thermal degradation of the package structure 300 is suppressed near the opening 116.

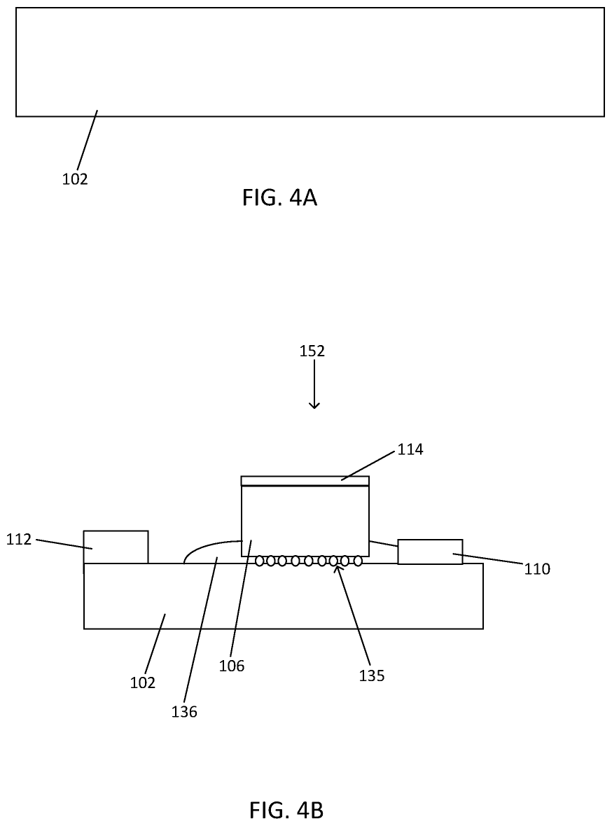

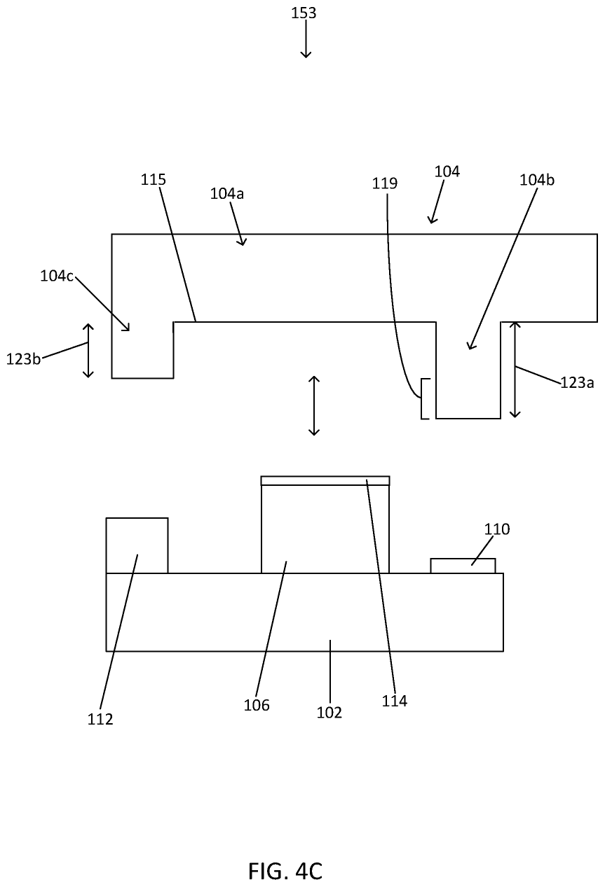

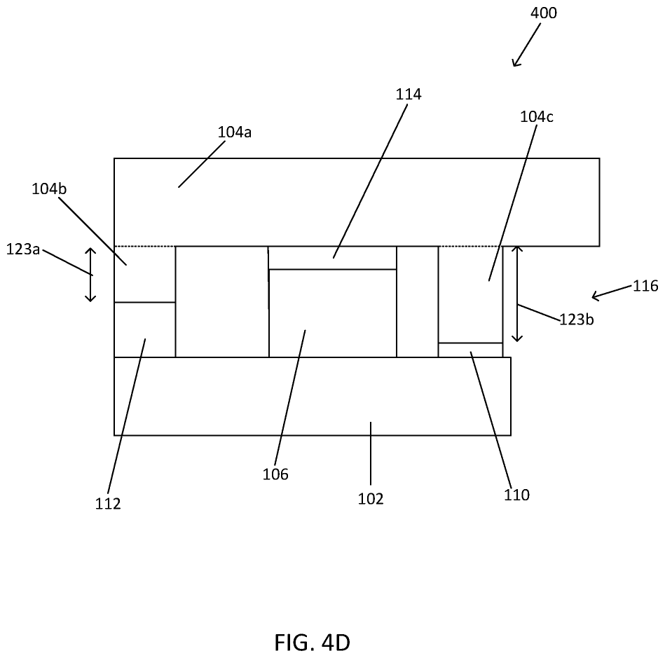

FIGS. 4A-4D depict a method of fabricating a package structure such as the package structure depicted in FIG. 1E. FIG. 4A depicts a portion of a package substrate 102. The package substrate 102 may comprise any suitable substrate with which to attach die and build an optical package structure. In an embodiment the package substrate 102 may provide mechanical support and provide electrical communication within a package structure and between devices coupled with such a package structure. In an embodiment the package substrate 102 may comprise an interposer or a board.

In FIG. 4B a process 152 may include a die attach process, wherein a die 106 and optical die (not shown) may be attached to the substrate 102 by solder structures 135. An underfill material 136 may be formed around the solder structures 135. Optical die may be attached adjacent to the die 106. An interface material 112, which may comprise a silicone based material in an embodiment, may be formed on the package substrate 102 adjacent to the die 106. The interface material 112 may be formed on the substrate 102 by utilizing a dispensing or stencil application, for example. The interface material 112 may comprise a second interface material 112 in an embodiment and may comprise a thickness of between about 100 microns to about 200 microns in an embodiment.

The die 106 may comprise a central processing unit (CPU) or a field programmable gate array (FPGA) die, for example or may comprise any suitable logic die for the particular application. Process 152 may additionally include the formation of an additional interface material 110 that may be formed adjacent to the die 106, wherein the additional interface material may comprise a first interface material 110.

The first interface material 110 may be formed on the package substrate utilizing a dispensing process or a screen/stencil or printable process, for example. In an embodiment, the first interface material 110 may comprise an electrically conductive adhesive material (ECA), for example. The first interface material 110 may comprise a thickness of between about 10 microns to about 20 microns, in an embodiment. A thermal interface material (TIM) 114 may be formed on a surface of the die 106.

FIG. 4C depicts an attachment process 153 wherein an IHS 104 is attached to the substrate 102. In an embodiment, the IHS 104 may comprise a lid portion 104a, a first foot portion 104b and a second foot portion 104c. The first foot portion 104b of the IHS 104 may comprise a length 123a which is greater than a length 123b of the second foot portion 104c. In an embodiment a portion of the second foot portion 104c may be removed prior to attachment of the IHS 104 to the package substrate 102, as shown in FIG. 2C for example. The portion of the second foot portion 104b of the IHS 104 may be removed utilizing such processes as a polishing or machining process for example.

In an embodiment, about 10 microns to about 180 microns may be removed from the second foot portion 104c of the IHS 104. Thus, the length 123a of the first foot portion 104b may be greater than a length 123b of the second foot portion 104c and may greater by the length of a foot extension 119.

Subsequent to the attachment process 153, the first foot portion 104b including the foot extension 119 of the IHS may be attached to the first interface material 110, the TIM 114 may be attached to the lid portion 104a of the IHS 104 and the second foot portion 104c may be attached to the second interface material 110 to form package structure 400 (FIG. 4D). By utilizing the foot extension 119 of the first foot 104b to attach to the package structure 102 with the first interface material 110, coupling of the IHS 104 to the package substrate 102 near opening 116 of the IHS 104 is enhanced and thus thermal degradation of the package structure 400 is suppressed.

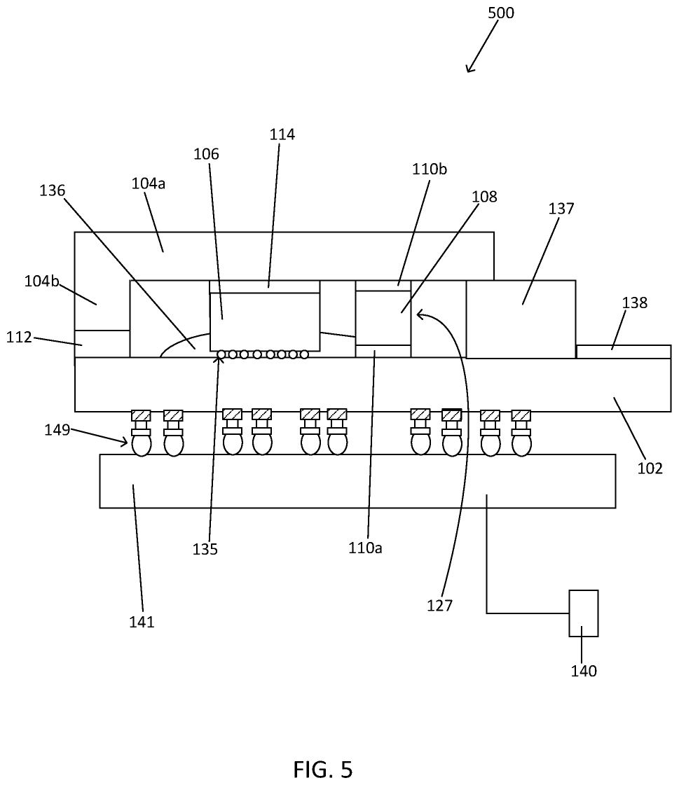

FIG. 5 depicts an IC package structure 500, such as an optical package structure according to embodiments herein. The package structure 500 may comprise non-optical die 106 and optical die (not shown) coupled thereto, as depicted in FIG. 1B for example, wherein the die 106 and optical die are on a package substrate 102. In some embodiments, the die 106 may comprise chiplet structures which may comprise components of a system on a chip (SOC) structure.

Any number of die/devices 106 may be coupled to the package substrate 102. The package substrate 102 may be coupled to a board 141, such as a printed circuit board, in an embodiment. The board 141 may be coupled to the package substrate 102 through solder structures 149 in an embodiment. A power supply 140, which may comprise any suitable power supply as known in the art, may be coupled to die 106 via IC package substrate 102, in an embodiment. An IHS 104 may comprise a coupling enhancement structure 127, which may comprise a support structure 108 bonded to the package substrate 102 with a first portion of a first interface material 110a bonding a first side of the support structure 108 to the package substrate 102 and a second portion of the first interface material 110b bonding a second side of the support structure feature 108 to a lid portion 104a of the IHS 104.

A foot portion 104b of the IHS 104 is attached/bonded to the package substrate 102 with a second interface material 112. In other embodiments, the coupling enhancement structure 127 may comprise a foot extension structure such as is depicted in FIG. 1E for example. Solder interconnect structures 135 may couple the die 106 to the substrate 102. A FAU 138 may be coupled to optical die 137 that may be coupled to the die 106 by any suitable coupling structures as are known in the art. An underfill material 136 surrounds the solder structures 135, in an embodiment.

Discussion now turns to operations for assembling and/or fabricating the discussed structures.

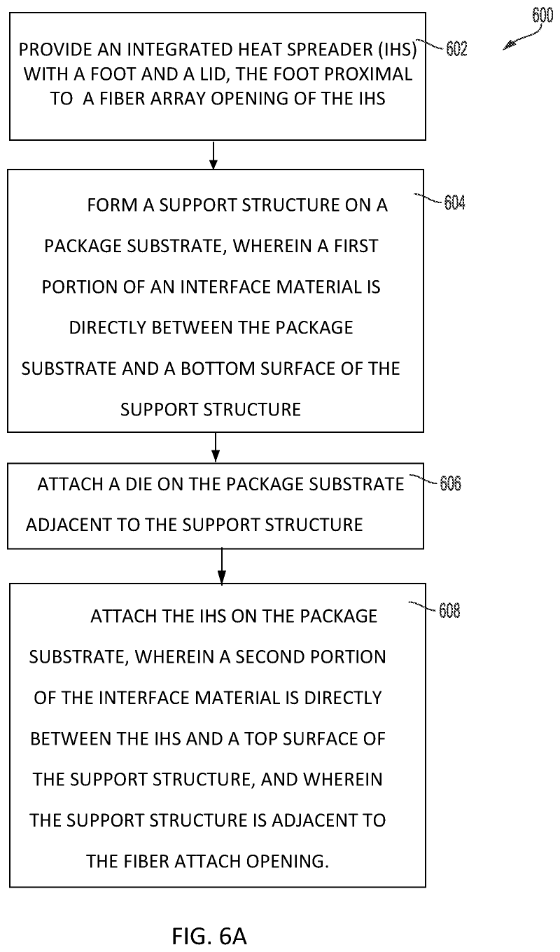

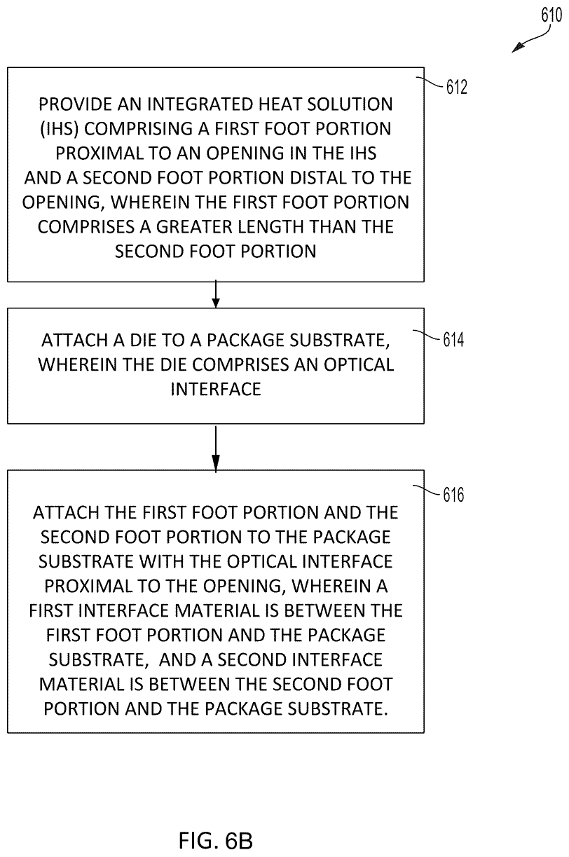

FIG. 6A is a flow chart of a process 600 of fabricating package structures according to some embodiments. For example, process 600 may be used to fabricate any of the microelectronic IC package structures of FIGS. 3A-3D.

As set forth in block 602, an integrated heat spreader (IHS) may be provided, wherein the IHS may comprise a fiber attachment opening. The (IHS) may comprise any suitable thermal solution, such as a heat spreader for example and may be employed as a thermal solution for a package substrate. In an embodiment, the IHS may comprise one or more fiber array openings so that an optical coupling unit/interface may be coupled to a die, such as logic and/or optical die, within a package substrate. The IHS comprises a lid, and foot proximate to the fiber array opening.

At block 604, a support structure may be formed on a package substrate. The package substrate may be utilized with an optical package system, such as any of the optical package structures/systems described in the present disclosure. The support structure may comprise any suitable material which provides mechanical support for the coupling of the IHS to a package substrate. The support structure may be formed utilizing any suitable formation processes, such as are known in the art. For example, the support structure may be formed utilizing a machining process.

In an embodiment, the support structure may comprise a conductive strip, and may comprise any suitable conductive materials such as a copper or a copper alloy material for example. The support structure may comprise any suitable dimensions depending upon the particular application, and may comprise a rectangular, a square shape or a spherical shape, in some embodiments. In an embodiment, the support structure may comprise a thickness that may be optimized to provide support between the package structure and the lid of the IHS.

The support structure may be bonded on an interface material that may be previously formed on the package substrate. The interface material may be formed on the package substrate utilizing a dispensing process or a screen/stencil or printable process, for example. In an embodiment, the interface material may comprise a first interface material and may comprise an electrically conductive adhesive material (ECA), for example. The first interface material may comprise such materials as silver filled silicone materials or silver filled epoxy materials for example.

In an embodiment, the first interface material may comprise an elastic modulus greater than about 9 GPa, but the elastic modulus may be tuned for the particular application. In an embodiment, the first interface material may comprise a thickness of between about 10 microns to about 20 microns but may be optimized for the particular application. In an embodiment, a first portion of the first interface material may be directly on a bottom surface of the support feature, between the support structure and the package substrate. A second interface material may be formed adjacent the die opposite the first interface material. The first interface material comprises a greater elastic modulus than the second interface material. A second portion of the first interface material may be formed on a top surface of the support structure.

At block 606, a die may be attached on the package substrate adjacent to the support structure. The die may comprise a central processing unit (CPU) or a field programmable gate array (FPGA) die, for example or may comprise any suitable logic die for the particular application. The die may be attached with a plurality of interconnect structures such as solder balls, utilizing any suitable die attach process, as are known in the art. One or more optical die may be attached to the substrate adjacent to the die and may be coupled to the die utilizing any suitable coupling processes. An underfill material may surround the solder balls. A TIM may be formed on a top surface of the die, and a second portion of the first interface material may be formed on a top surface of the support structure.

At block 608, the IHS may be attached on the package substrate, wherein the second portion of the first interface material is directly between a portion of the lid of the IHS and the support structure. In an embodiment, the first and second portions of the first interface material may comprise the same materials, but in other embodiments, the first and second portions may comprise different materials from each other. The IHS may be attached to the package structure utilizing any suitable attachment process. The support structure that is attached to the package structure and the IHS near the fiber array opening minimizes the utilization of packaging area while decreasing dynamic warpage during temperature cycling of the package structures of the embodiments disclosed herein. The foot portion of the IHS is attached to the package structure with the second interface material, farther away from the fiber array opening.

FIG. 6B is a flow chart of a process 610 of fabricating package structures according to some embodiments. For example, process 610 may be used to fabricate any of the microelectronic IC package structures of FIG. 4A-4D.

As set forth in block 612, an integrated heat spreader (IHS) may be provided, wherein the IHS may comprise a lid, a first foot portion and a second foot portion. The first foot portion may be located near an opening in the HIS and comprises a greater length thean the second foot portion. The opening in the IHS provides for an optical coupling structure, such as a FAU to be coupled to a die, including optical die located on a package substrate. The opening may comprise a fiber attachment opening. The IHS may comprise any suitable thermal solution, such as a heat spreader for example and may be employed as a thermal solution for a package substrate.

At block 614, a die may be attached on the package substrate adjacent to the IHS opening. The die may comprise a central processing unit (CPU) or a field programmable gate array (FPGA) die, for example or may comprise any suitable logic die for the particular application. The die may be attached utilizing any suitable die attach process, as are known in the art. One or more optical die may be coupled to the die utilizing any suitable coupling processes. A first interface material and a second interface material may be formed opposite each other adjacent to the die, with the first interface material proximal to the IHS opening. A TIM may be formed on a top surface of the die. The first interface material comprises a greater elastic modulus than the second interface material.

At step 618, the first foot portion and the second foot portion of the IHS may be attached to the package substrate, utilizing any suitable attaching process. The first foot portion is bonded/attached to the first interface material, which may comprise an electrically conductive adhesive. The first interface material is between the first foot portion and the package substrate. In an embodiment, the first interface material may comprise a thickness of between about 10-20 microns but may be optimized for the particular application.

In an embodiment, the second foot portion is attached/bonded to the package substrate by the second interface material, and is farther away from the IHS opening than the first foot portion. In an embodiment, the second interface material may comprise an elastic modulus that is less than about 20 MPa. In an embodiment, the second interface material may comprise a thickness of between about 100 to about 200 microns but may be optimized for the particular application. Because the first foot portion is attached to the package structure with the stronger first adhesive material near the IHS opening, dynamic warpage during temperature cycling of the package structure is suppressed in the embodiments disclosed herein.

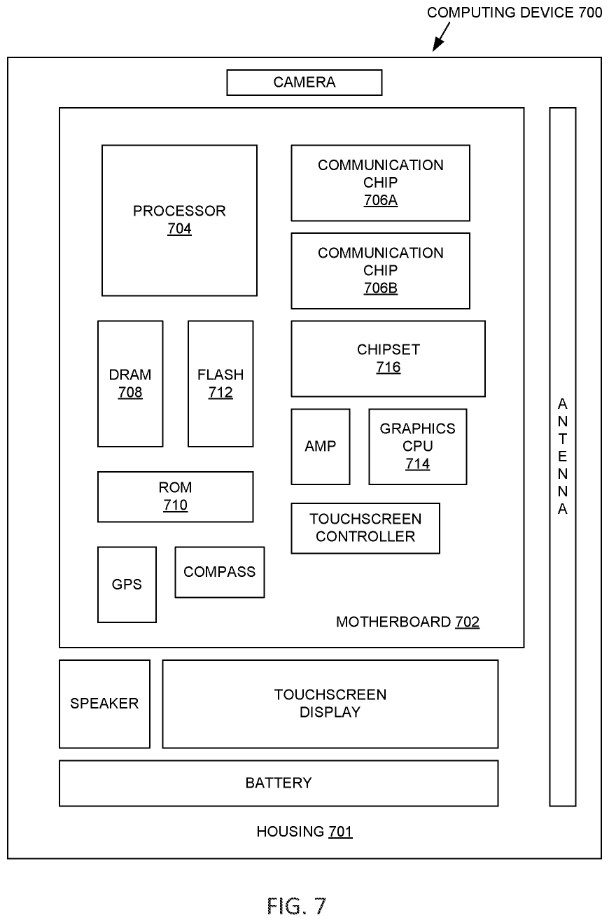

FIG. 7 illustrates an electronic or computing device 700 in accordance with one or more implementations of the present description. The computing device 700 may include a housing 701 having a board 702 disposed therein. The computing device 700 may include a number of integrated circuit components, including but not limited to a processor 704, at least one communication chip 706A, 706B, volatile memory 708 (e.g., DRAM), non-volatile memory 710 (e.g., ROM), flash memory 712, a graphics processor or CPU 714, a digital signal processor (not shown), a crypto processor (not shown), a chipset 716, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 702. In some implementations, at least one of the integrated circuit components may be a part of the processor 704.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include an apparatus having a package substrate coupled with an integrated heat spreader (IHS) comprising a lid and a foot portion that is over the package substrate. The package comprises a support structure on the package substrate adjacent to a fiber attach opening. A first portion of a first interface material is between the package substrate and a bottom surface of the support structure and a second portion of the first interface material is between the lid of the IHS and the support structure. A second interface material is directly between the foot portion of the IHS and the package substrate. A die is on the package substrate adjacent to the support structure and is attached to the lid with a TIM material.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-6. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein the first embodiment is a package substrate, an integrated heat solution (IHS) over the package substrate. The IHS comprises a lid and a foot proximal an opening in the HIS. A support structure is spaced apart from the foot and comprises a first interface material in contact with the package substrate. The lid is in contact with the support structure and a second interface material is directly between the foot of the IHS and the package substrate. A die is on the package substrate adjacent to the support structure, the die having an optical interface proximal to the opening.

In second examples the first example further comprises wherein the package substrate further comprises a second interface material, wherein the second foot portion is directly on the second interface material, and wherein the second interface material has a different chemical composition than the first interface material.

In third examples 2 further comprises wherein the package substrate further comprises a second interface material, wherein the second foot portion is directly on the second interface material, and wherein the second interface material has a different chemical composition than the first interface material.

In fourth examples any of examples 2-3 further comprises wherein the second interface material comprises an epoxy material and the first interface material comprises one of an electrically conductive adhesive material or a non-conductive adhesive material.

In fifth examples wherein any of examples 1˜4 further comprises a second opening in the IHS opposite the first opening wherein a third foot is proximal to the second opening and the fourth foot is spaced apart from the third foot, the third foot portion extending a greater length from the lid than the fourth foot.

In sixth examples wherein any of examples 1-5 further comprises wherein the first interface material comprises a first thickness and the second interface material comprises a second thickness, wherein the first thickness is less than the second thickness.

In seventh examples wherein any of examples 1-6 further comprises wherein a thermal interface material (TIM) is between the lid portion of the IHS and the die and wherein the length of the first foot portion is between about 10 microns to about 180 microns greater than the second foot portion.

In eighth examples wherein example 7 further comprises wherein the TIM comprises a polymer-based TIM material.

In ninth examples wherein any of examples 1-8 further comprises the die comprises a FPGA or a CPU die.

In tenth examples wherein examples 9 further comprising a fiber array unit (FAU) is coupled to the one or more optical die.

In eleventh examples the tenth example further comprising a fiber array unit (FAU) coupled to the one or more optical die.

A twelfth example is an apparatus, comprising a package substrate, an integrated heat solution (IHS) over the package substrate, wherein the IHS comprises a lid and a foot proximal an opening in the HIS, a support structure spaced apart from the foot and comprising a first interface material in contact with the package substrate, the lid in contact with the support structure, a second interface material directly between the foot of the IHS and the package substrate, and a die on the package substrate adjacent to the support structure, the die comprising an optical interface proximal to the opening.

In thirteenth examples example 12 further comprises wherein the first interface material is in contact with the lid.

In fourteenth example 13 further comprises wherein the support structure comprises metal between a first portion of the first interface material in contact with the package substrate and a second portion of the first interface material in contact with the lid.

In fifteenth examples example 13 further comprises wherein at least one of the first portion of the first interface material or the second portion of the first interface material comprises an electrically conductive adhesive material.

In sixteenth examples any of examples 12-15 further comprise a second support structure spaced apart from the foot and comprising the first interface material in contact with the package substrate, wherein the support structure is on one side of the opening and the second support structure is on a second side of the opening opposite the first side.

In seventeenth examples any of examples 12-16 further comprising wherein the IHS comprises a first opening and a second opening opposite the first opening, wherein a first set of support structures is adjacent to the first opening and a second set of support structures is adjacent to the second opening.

An eighteenth example is a method comprising: providing an IHS comprising a lid, a first foot portion proximal to an opening in the IHS and a second foot portion spaced apart from the opening by the first foot portion; attaching a die to a package substrate, wherein the die comprises an optical interface; and attaching the first foot portion and the second foot portion of the IHS to the package substrate with the optical interface proximal to the opening, wherein a first interface material is between the first foot portion and the package substrate, and a second interface material is between the second foot portion and the package substrate.

In nineteenth examples example 18 further comprises wherein a length of the first foot portion is greater than a length of the second foot portion.

In twentieth examples any of examples 18-19 further comprises wherein attaching the die comprises attaching one of a FPGA or a CPU die and coupling one or more optical die to the die.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a package substrate;
an integrated heat spreader (IHS) over the package substrate, wherein the IHS comprises a lid, a first foot portion proximal an opening in the IHS and a second foot portion spaced apart from the opening by the first foot portion, the first foot portion extending a greater length from the lid than the second foot portion;
an interface material on the package substrate, wherein the first foot portion is directly on the interface material; and
a die on the package substrate adjacent to the first foot portion, the die comprising an optical interface proximal to the opening.

2. The apparatus of claim 1, wherein the package substrate further comprises a second interface material, wherein the second foot portion is directly on the second interface material, and wherein the second interface material has a different chemical composition than the interface material, wherein the interface material comprises a first interface material.

3. The apparatus of claim 2, wherein the second interface material has a lower elastic modulus than an elastic modulus of the first interface material and wherein a length of the first foot portion is between about 10 microns to about 180 microns greater than a length of the second foot portion.

4. The apparatus of claim 2, wherein the second interface material comprises an epoxy material and the first interface material comprises one of an electrically conductive adhesive material or a non-conductive adhesive material.

5. The apparatus of claim 1, further comprising a second opening in the IHS opposite the opening wherein a third foot is proximal to the second opening and a fourth foot is spaced apart from the third foot, the third foot extending a greater length from the lid than the fourth foot.

6. The apparatus of claim 2, wherein the interface material comprises a first thickness and the second interface material comprises a second thickness, wherein the first thickness is less than the second thickness.

7. The apparatus of claim 1, wherein a thermal interface material (TIM) is between the lid of the IHS and the die and wherein a length of the first foot portion is between about 10 microns to about 180 microns greater than the second foot portion.

8. The apparatus of claim 7, wherein the TIM comprises a polymer-based TIM material.

9. The apparatus of claim 1, wherein the die comprises a FPGA or a CPU die.

10. The apparatus of claim 9, wherein one or more optical die are coupled with the die.

11. The apparatus of claim 10, further comprising a fiber array unit (FAU) is coupled to the one or more optical die.

12. An apparatus, comprising:
a package substrate;
an integrated heat solution (IHS) over the package substrate, wherein the IHS comprises a lid and a foot proximal an opening in the IHS;
a support structure spaced apart from the foot and comprising a first interface material in contact with the package substrate, the lid in contact with the support structure;
a second interface material directly between the foot of the IHS and the package substrate; and
a die on the package substrate adjacent to the support structure, the die comprising an optical interface proximal to the opening.

13. The apparatus of claim 12, wherein the first interface material is in contact with the lid.

14. The apparatus of claim 13, wherein the support structure comprises metal between a first portion of the first interface material in contact with the package substrate and a second portion of the first interface material in contact with the lid.

15. The apparatus of claim 13, wherein at least one of a first portion of the first interface material or a second portion of the first interface material comprises an electrically conductive adhesive material.

16. The apparatus of claim 12, comprising a second support structure spaced apart from the foot and comprising the first interface material in contact with the package substrate, wherein the support structure is on a first side of the opening and the second support structure is on a second side of the opening opposite the first side.

17. The apparatus of claim 12, wherein the IHS comprises a first opening and a second opening opposite the first opening, wherein a first set of support structures is adjacent to the first opening and a second set of support structures is adjacent to the second opening.

18. A method, comprising:
providing an IHS comprising a lid, a first foot portion proximal to an opening in the IHS and a second foot portion spaced apart from the opening by the first foot portion;
attaching a die to a package substrate, wherein the die comprises an optical interface; and
attaching the first foot portion and the second foot portion of the IHS to the package substrate with the optical interface proximal to the opening, wherein a first interface material is between the first foot portion and the package substrate, and a second interface material is between the second foot portion and the package substrate.

19. The method of claim 18, wherein a length of the first foot portion is greater than a length of the second foot portion.

20. The method of claim 18, wherein attaching the die comprises attaching one of a FPGA or a CPU die and coupling one or more optical die to the die.
